(19) United States
(12) Patent Application Publication
(10) Pub. No.: US 2025/0277855 A1
(43) Pub. Date: Sep. 4, 2025

(54) NON-TRANSITORY DIFFERENTIAL PHYSICS NETWORK

(71) Applicant: NISSAN NORTH AMERICA, INC., Franklin, TN (US)

(72) Inventors: Amir TAQIEDDIN, Farmington Hills, MI (US); Masanobu UCHIMURA, Farmington Hills, MI (US); Balachandran GADAGUNTLA RADHAKRISHNAN, San Mateo, CA (US); Shigemasa KUWATA, Palo Alto, CA (US)

(21) Appl. No.: 18/592,381

(22) Filed: Feb. 29, 2024

(51) Int. Cl. G01R 31/36; B60L 58/16; G01R 31/367; G01R 31/392

(52) U.S. Cl. CPC G01R 31/3648; B60L 58/16; G01R 31/367; G01R 31/392

(57) ABSTRACT

A non-transitory differential physics network disposed upon a non-transitory computer readable storage medium and executable by a computer is provided. The non-transitory differential physics network includes an input layer, an output layer and an intermediate layer. First input values related to a first set of detected battery state values is input to the input layer. A total capacity loss value is output from the output layer. Second input values related to a second set of detected battery state values is input to the intermediate layer. The differential physics network utilizes differential physics to determine the directional relationship of the first and second sets of detected battery state values to output the output layer. The differential physics network performs optimization using backpropagation to determine target input values for the input layer.

### BACKGROUND

### Technical Field

The present disclosure generally relates to a non-transitory differential physics network. More specifically, the present disclosure relates to a non-transitory differential physics network integrated with a battery management system.

### Background Information

Extending the lifetime of the batteries is a critical factor for the consumers. Longer lifetime of the batteries in electric vehicles (EVs) can primarily elevate the investment return for purchasing EV and reduce the demands for raw materials to make newer batteries. The extended lifetime of batteries can be achieved by minimizing their degradations. State-of-health (SOH), the ratio of the remaining capacity with respect to the original capacity, represents one of the indicators of the lifetime of the battery.

### SUMMARY

In view of the state of the known technology, one aspect of the present disclosure is to provide a non-transitory differential physics network disposed upon a non-transitory computer readable storage medium and executable by a computer. The non-transitory differential physics network comprises an input layer, an output layer and an intermediate layer. First input values related to a first set of detected battery state values is input to the input layer. A total capacity loss value is output from the output layer. Second input values related to a second set of detected battery state values is input to the intermediate layer. The differential physics network utilizes differential physics to determine the directional relationship of the first and second sets of detected battery state values to output the output layer. The differential physics network performs optimization using backpropagation to determine target input values for the input layer.

In view of the state of the known technology, one aspect of the present disclosure is to provide a method for determining target control parameters for a vehicle battery. The method comprises detecting a first set of battery state values. The method further comprises detecting a second set of battery state values. The method further comprises utilizing differential physics via a differential physics network to determine the directional relationship of the first and second sets of battery state values to calculate a total capacity loss value. The method further comprises performing optimization via the differential physics network using backpropagation to determine the target control parameters for the vehicle battery.

### BRIEF DESCRIPTION OF THE DRAWINGS

Referring now to the attached drawings which form a part of this original disclosure:

FIG. 1 is a schematic view of an electrified vehicle having a battery management system with an electronic controller having a differential physics network;

FIG. 2 is a schematic view of the differential physics network;

FIG. 3 is another schematic view of the differential physics network with inputs provided at the battery cell level;

FIG. 4 is a neural map-like view of the differential physics network;

FIG. 5 is a simplified neural map-like view of the differential physics network;

FIG. 6 is a graph of calculating a capacity loss using the differential physics network;

FIG. 7 is a flowchart of the processing steps performed by the differential physics network;

FIG. 8 is a block diagram of the overall functions of the electronic controller of the battery management system;

FIG. 9 is a schematic view of sample drive modes that generate a different activation function for the electronic controller;

FIG. 10 is a neural map-like view of the differential physics network performing an activation function calculation;

FIG. 11 is a flowchart of the processing steps of the electronic controller;

FIG. 12 is another flowchart of additional processing steps of the electronic controller; and

FIG. 13 is a block diagram of the processing steps of the battery management system.

### DETAILED DESCRIPTION OF EMBODIMENTS

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

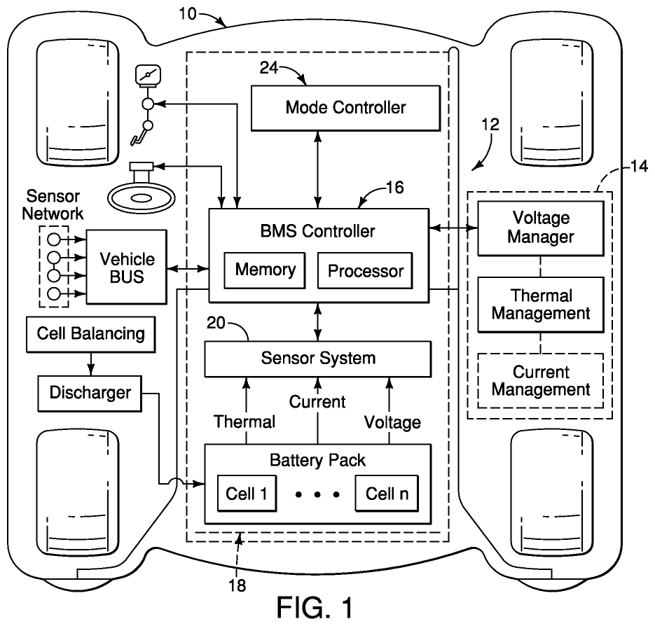

Referring initially to FIG. 1, a vehicle 10 is provided with a vehicle battery management system is provided. That is, the vehicle battery management system (hereinafter “BMS 12”) is implemented with the vehicle 10 as will be described below. The BMS 12 comprises a battery management circuitry 14 and an electronic controller (hereinafter “BMS controller 16”). The BMS 12 of the illustrated embodiment is considered an on-board BMS 12 for the vehicle. That is, the BMS 12 is an on-board BMS 12 that can be implemented for electrified vehicles such as electric vehicles and hybrid electric vehicles that are powered by vehicle batteries.

The vehicle is powered by one or more electric-vehicle batteries (only one illustrated schematically in FIG. 1). The BMS 12 is provided for managing the vehicle's 10 batteries. For simplicity, the BMS 12 will be described with reference to one vehicle battery 18 but it will be apparent to those skilled in the vehicle and the battery field from this disclosure that the BMS 12 can be implemented for managing multiple vehicle batteries as necessary and/or desired. As shown, the vehicle further comprises a sensor system 20 configured to detect a plurality of detected battery state values related to the vehicle battery 18. The sensor system 20 is an on-board sensor system 20. The detected battery state values are considered inputs that are transmitted to the BMS controller 16 of the BMS 12 for processing as will be further described below.

The battery 18 is a secondary (rechargeable) battery that is preferably a lithium-ion battery. Battery is comprised of cells and battery modules that make up the battery pack 16C for the battery. The cells are electrochemical cells that are the basic unit of the battery. The cells are assembled into one or more frames to protect the cells from external shocks, such as heat or vibration. The assembled cells in the frame together define the modules. The modules are then assembled together with the BMS 12 and a cooling device for controlling and managing the modules' internal temperature, voltage, etc. The assembled modules form the battery pack of the battery.

The battery management circuitry 14 of the BMS 12 includes a voltage management component, a thermal management component and a current management component. The BMS 12 and its components function to monitor the components of the battery 18. In particular, the BMS 12 monitors the current and voltages in the battery pack, the cells or the module. The BMS 12 is equipped with the voltage management component, the thermal management component and the current management component to manage the protocols of the battery 18.

The voltage management circuit is configured to control the charging and discharging protocol for the vehicle battery. The thermal management circuit is configured to control a heating and cooling protocol for the vehicle battery 18. The current management circuit is configured to control a charging current protocol of the vehicle battery 18.

The voltage management component and the current management component control charging and discharging of the battery in accordance with load demands and charging from a variety of energy sources to optimize battery lifespan. The thermal management component manages the heating and cooling protocol of the battery. The battery management circuitry 14 manages the battery by removing charge from the most charged cells, which gives headroom for additional charging current to prevent overcharging, and allows the less charged cells to receive more charging current. The battery management circuitry 14 can redirect the charging current around the most charged cells, thereby allowing the less charged cells to receive charging current for a longer length of time.

The BMS 12 can manage a plurality of detected battery state values shown below:

TABLE 1

| Input (detected battery | |
|---|---|
| state value) | Description |
| Tamb | Ambient temperature |
| SOC | State-of-charge of the BATTERY |
| Iapp | Applied current during charging or regenerative |
| | braking |
| T | The estimated temperature at the battery pack |
| | level |
| Crate | The charging/discharging rate of the BATTERY |
| Vmin | Minimum voltage in the battery pack |
| Vmax | Maximum voltage in the battery pack |
| Tmin | Minimum temperature in the battery pack |
| Tmax | Maximum temperature in the battery pack |
| DOD | Depth of discharge |

The ambient temperature (Tamb) will have a relationship to the battery pack temperature (T). Depending on the ambient temperature (Tamb), the BMS 12 can control the temperature of the battery pack (T).

The BMS 12 can control the voltage, current, temperature, and state-of-health of the battery which can be used to optimize the following as shown below:

TABLE 2

| Input (detected battery | |
|---|---|
| state value) | Description |
| Pout | Output power from the battery |
| u | The speed of the battery |
| Pi | The power input to the battery (e.g., |
| | regenerative brakes) |

The power input (Pi) and output (Pout) are functions of the current and voltage of the battery. The speed (u) is part of the power output (Pout). The battery management circuitry 14 of the BMS 12 can be considered conventional. The BMS 12 of the illustrated embodiment is provided with the BMS controller 16 that is integrated with the battery management circuitry 14 and implements differential physics network 22, as explained below. The output of the differential physics network 22 is used by the BMS controller 16 and the battery management circuitry 14 to then manage the inputs or battery state values of the battery as will be discussed below.

The current state of art focuses on estimating state-of-health (SOH), state-of-charge (SOC) or remaining useful life (RUL) using either on-board (e.g., reduced order or simple empirical formulas) or cloud-based (e.g., ML) approaches. Conventional on-board approaches do not include highly accurate or robust models due to their computationally expensive cost. Additionally, conventional BMS controllers are focused on balancing the voltage or temperature between the cells without trying to maximize the lifetime of the battery cells. That is, the technical problem of conventional BMS's is that conventional BMS's lack a centralized controller for simultaneous multi-factor optimization. Therefore, the technical problem is that it is difficult to reduce battery SOH degradation using the current approaches in the conventional BMS 12. Overall, there is a significant need for computationally cost-effective solution(s) that can couple and control the factors which lead to the SOH loss.

Therefore, the BMS 12 of the illustrated embodiment is provided having the BMS controller 16 that executes a real-time optimization control for extending the lifetime of the battery. The BMS controller 16 is integrated with a differential physics network 22 that executes differential physics computations as a technical solution. The differential physics computation can be implemented on-board via the BMS controller 16 to determine the direction of battery degradation, durability, and remaining lifetime. The use of the differential physics network 22 is computationally inexpensive and practical in implementation. The approach requires knowing certain inputs for only the last and final steps.

Here, the BMS 12 having the integrated BMS controller 16 is a centralized multi-factor control system that can couple and optimize multi-variables at the same time in real-time. The BMS controller 16 uses the multiscale differential physics network 22 which is a computational framework which connects the main inputs in the battery (e.g., environment temperature, power input/output, SOC) with the capacity degradation using various indicators and factors. The differential physics network 22 is implemented as a control component that is integrated with the BMS 12 for balancing the battery parameters via real-time optimization on a cost-function to determine the appropriate charging/discharging protocol of the battery. Therefore, target control values are generated by the differential physics network 22 for reducing battery degradation and extending the lifetime of the battery. The BMS controller 16 is integrated with the BMS controller 16 to perform target capacity, current, temperature and voltage control to reduce overall battery degradation.

The technological improvement of the illustrated BMS 12 includes that the BMS controller 16 can account for cell-to-cell variation of the detected battery states through establishing differential interconnection between the cells and the battery pack. For example, the c-rate can be optimized using the BMS 12 to reduce the growth rate of the solid-electrolyte interphase (SEI) and the cathode-electrolyte interphase (CEI) layers and battery capacity loss/degradation associated with the loss of these SEI and CEI layers. In this case, the cost will be the charging/discharging time.

The technological improvement of the BMS 12 of the illustrated embodiment further includes accounting for SEI and CEI growth for setting target control values accordingly to reduce the battery degradation. It has been known that SEI and CEI growth are responsible for ten percent of the battery degradation over time. Therefore, optimizing the growth of these layers through target control values for the inputs can help in extending the lifetime of the battery, particularly target voltage and temperature values.

The technological improvement is also to provide a computationally cost-effective BMS 12 because the BMS 12 does not compute or estimate the actual value of each factor of the battery degradation or the overall degradation in the battery pack. Instead, the differential physics network 22 uses the directional information (i.e., partial derivatives) based on the real-time conditions to optimize the input values towards extending the lifetime of the battery pack.

As stated, the BMS controller 16 is configured to execute a differential physics computation via the differential physics network 22 using detected battery state values to determine target control values for the battery management circuitry 14. The BMS controller 16 is further programmed to control the battery management circuitry 14 in accordance with the target control values, as will be further discussed below. The BMS controller 16 is programmed to optimize to determine the target control values upon the differential physics network 22 performing backpropagation to generate the target control values, as will be further discussed below.

The vehicle further comprises a vehicle driving mode device having a mode controller 24. The mode controller 24 is programmed to select a drive mode of the vehicle from a plurality of preprogrammed drive modes. The BMS controller 16 is programmed to optimize in accordance with a selected drive mode of the plurality of preprogrammed drive modes, as will be further described below.

As stated, the sensor system 20 detects a plurality of detected battery state values. The sensor system 20 consists of different sensors to monitor and measure battery parameters including voltage, temperature, current of the battery and its components, etc. The sensor system 20 can be conventional. The detected battery state values (first detected battery state values or first input values 26) include any one or more of a vehicle ambient temperature value, a vehicle state of charge value, a vehicle output power value, an applied current value, and a battery pack temperature value. The detected battery state values (second detected battery state values or second input values 28) further include any one or more of a vehicle charging/discharging rate value, a vehicle speed value, a vehicle power input value, a minimum battery voltage value, a maximum battery voltage value, a minimum battery temperature value, a maximum battery temperature value, and a depth of discharge value. The BMS 12 can directly or indirectly control all of the first and second input values 28 mentioned herein.

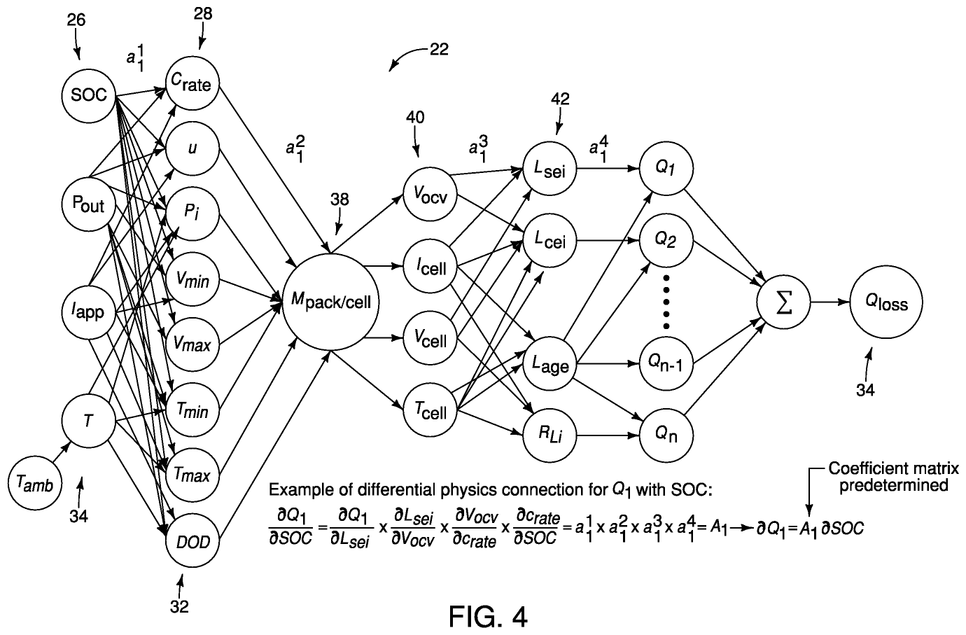

The non-transitory differential physics network 22 is disposed upon a non-transitory computer readable storage medium and executable by a computer. The differential physics network 22 can be integrated with the BMS controller 16. Referring to FIG. 4, the non-transitory differential physics network 22 comprises an input layer 30, an intermediate layer 36 32 and an output layer 34. The processing of the differential physics network 22 mimics a neural network structure by linking different variables (e.g., inputs) each in a node. All the variables and inputs are different layers are connected by directional relationship (partial derivative). The differential physics network 22 relies on using directional optimization to determine the exact parameters for every physical relationship between the inputs aid the outputs.

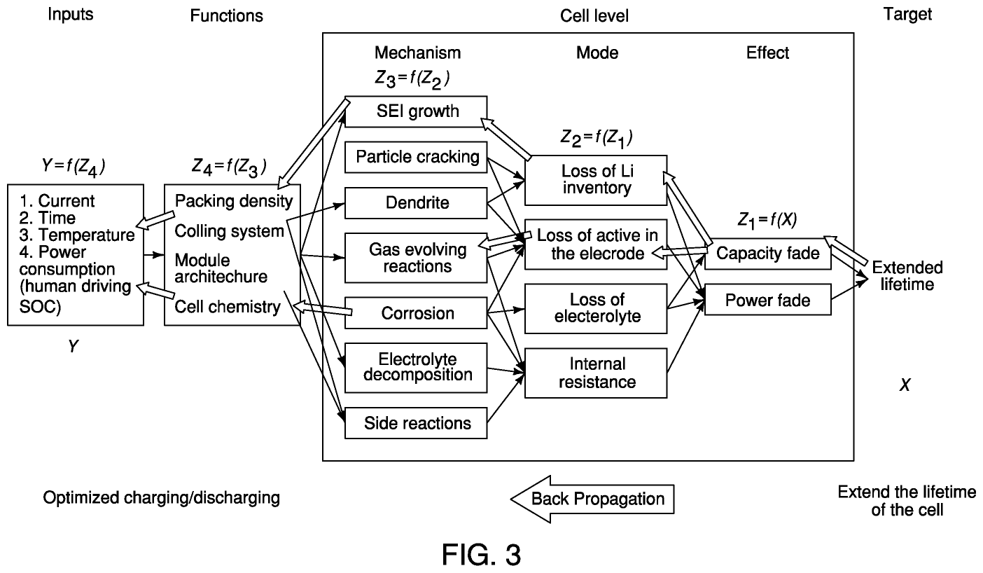

The BMS controller 16 having the differential physics network 22 is unlike the current onboard methods which are limited to reduce order approaches that do not account for various physical conditions due to the expensive computational costs. Here, the differential physics network 22 is provided as a vehicle onboard to optimize the charging protocols and inform the driver about the best practices for extended the lifetime of the vehicle battery. The differential physics network 22, the methods provided and the BMS controller 16 can utilize inputs from any of the battery cell level, the module level, the battery pack level and the vehicle level. FIG. 3 shows an example of the differential physics network 22 utilizing battery state values at the battery cell level.

Referring to FIG. 4, the first input values 26 related to the first set of detected battery state values 26 is input to the input layer 30. The differential physics network 22 further comprises an intermediate layer 32 to which second input values related to a second set of detected battery state values 28 is input. Each of the first set of detected battery state values 26 is connected by a directional relationship to each of the second set of detected battery state values 28. In the illustrated embodiment, the differential physics network 22 utilizes differential physics to determine the directional relationship of the first and second sets of detected battery state values 26 and 28 to output the output layer 34. That is, the differential physics network 22 performs differential physics computation on a continuous basis during vehicle real-time use to determine the directional relationship between the detected battery states and the overall degradation or capacity loss of the battery.

As shown, the differential physics network 22 further comprises a conversion layer 38 where a conversion function that converts the first and second input values are executed. In particular, the conversion layer 38 outputs first directional derivative cell level values 40. The first directional derivative cell level values 40 include any one or more of an open-circuit voltage value, an electrical current value, an electrical voltage value, and a temperature value all at the battery cell level. The conversion layer 38 further outputs second directional derivative cell level values. The second directional derivate cell level values 42 include any one or more of an solid electrolyte interface thickness value, a cathode electrolyte interphase thickness value, a current cycle number value, an electrical resistance value at the battery cell level. The first and second directional derivative cell level values all relate to the battery cell level. That is, FIGS. 3 and 4 illustrate the differential physics network 22 utilizing inputs and outputs relating to the battery cell level.

In this way, the differential physics network 22 connects multiple detected battery input values at different scales and uses these values for ultimate controlling of the battery degradation conditions. For example, the environment temperature (e.g, T_{amb}) at macroscopic level can be connected to the degradation by the solid-electrolyte interphase (SEI)/cathode-electrolyte interphase (CEI) at nanoscale via directional derivatives which links the macroscopic input with the nanoscale effect through going across the vehicle level, the battery pack level, the module level and the cell level. This allows for considering various degradation factors and mechanisms in one optimization framework. For example, optimizing the battery input values to control the growth of the SEI/CEI can allow for extending the battery lifetime by ten percent. Also, optimizing the SOC level with avoiding any overcharging can allow extending the lifetime of the battery by twenty percent. The directional derivatives are linked to each other via the chain rule by a differential physics map that mimics a neural network structure.

Referring to FIG. 4, the partial derivatives are connected with each other from different levels for a given direction using the chain rule. For example, the degradation of the battery cell due to SEI growth can be written as the change of capacity due to the SEI as a function of SOC change:

$$\partial {Q}_{1} = {A}_{1} \partial SOC \qquad Formula 1$$

where A₁ is a directional coefficient matrix that is pre-determined in the car. Here, the objective is to find the optimum

∂SOC

towards minimizing the value of

∂Q₁.

The function of the SOC is connected as

$$\frac{\partial {Q}_{1}}{\partial SOC}$$

in the directional change of capacity due the SEI degradation mode as a function of the SOC The function is the direction of capacity loss due to SET thickness by SET thickness change due to the open circuit voltage change by open circuit voltage change due to c-rate value x c-rate value change due to the SOC level.

The overall computation can be mathematically written in order as follows:

$$\frac{\partial {Q}_{1}}{\partial SOC} = \frac{\partial {Q}_{1}}{\partial {L}_{sei}} \times \frac{\partial {L}_{sei}}{\partial {V}_{ocv}} \times \frac{\partial {V}_{ocv}}{\partial {c}_{rate}} \times \frac{\partial {c}_{rate}}{\partial SOC} \qquad Formula 2$$

Each derivative occurs at a given layer (scale). A simplified version of Formula 2 can be written as below:

$$\frac{\partial {Q}_{1}}{\partial SOC} = {α}_{1}^{1} \times {α}_{1}^{2} \times {α}_{1}^{3} \times {a}_{1}^{4} = {A}_{1} \qquad Formula 3$$

where each superscript represents a corresponding layer or scale in the differential physics network 22.

The differential physics network 22 further comprises an output layer 34 from which a total capacity loss value Qₗₒₛₛ (e.g., battery degradation) is output. The differential physics network 22 performs optimization during real-time battery use. The differential physics network 22 executes optimization via backpropagation to minimize the error, difference or loss between the ideal capacity and the current battery capacity. By doing so, the differential physics network 22 is provided to determine and continuously update the target input values for reducing the battery degradation during vehicle battery use as necessary. In the illustrated embodiment, “target input values” also refers to “target control values” for controlling the inputs by the BMS controller 16.

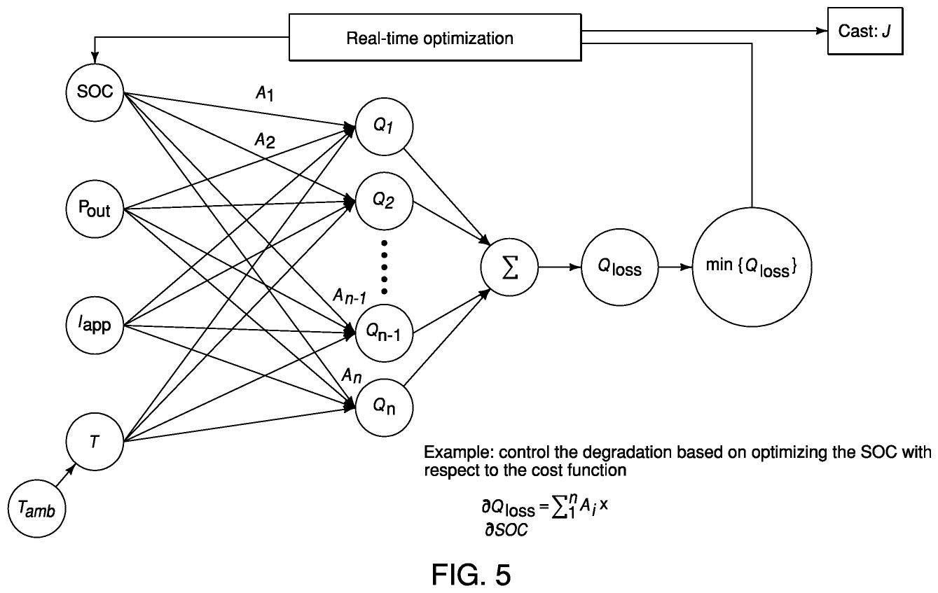

The optimization is performed using a cost function of the total capacity loss Qₗₒₛₛ based on varying the first and second input values. In particular, as seen in FIG. 5, the optimization of the differential physics network 22 is carried out using real-time optimization method with the cost function of J. The cost function can be determined based on the target input values (cause of degradation Y). For example, if the optimization is performed based on selecting an optimized charging protocol, then the optimization cost will be the time for battery charging given that slower charging reduces the degradation in the battery. In this way, the differential physics network 22 performs optimization using backpropagation to determine target input values for the input layer 30. FIG. 5 illustrates an optimization schematic where the objective is to minimize the capacity loss Qₗₒₛₛ between the ideal value and actual capacity as a function of time.

As shown in FIGS. 4 and 5, the non-transitory differential physics network 22 outputs the total capacity loss value Qₗₒₛₛ based on a plurality of capacity loss values (Q₁ . . . Qₙ), each of the capacity loss values being associated with a value from the first and second input values. The total capacity loss value of the output layer 34 is determined from a summation of the plurality of capacity loss values (Q₁ . . . Qₙ).

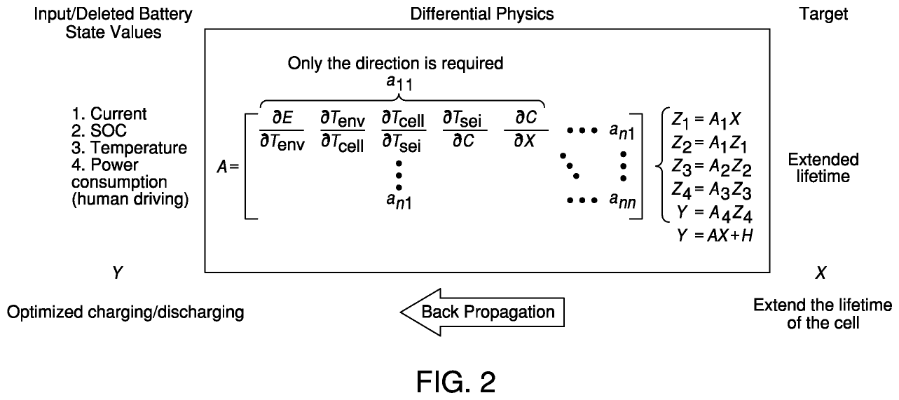

Referring to FIG. 2, backpropagation determines the target input values (cause of degradation Y) by solving the linear system:

$$Y = A X + H \qquad Formula 4$$

where the value X is the target variable for the extended lifetime such as the capacity loss Qₗₒₛₛ, SOH, or RUL, and where the value H is the historical information from last cycle step. The value A is the pre-determined coefficient matrix. The value Aᵢ is the coefficient at layer that connects the physical input Zᵢ with either X, Y or Zᵢ₊₁. In this illustrated example, the optimization is done to extended the lifetime of the battery with respect to the charging or discharging rate.

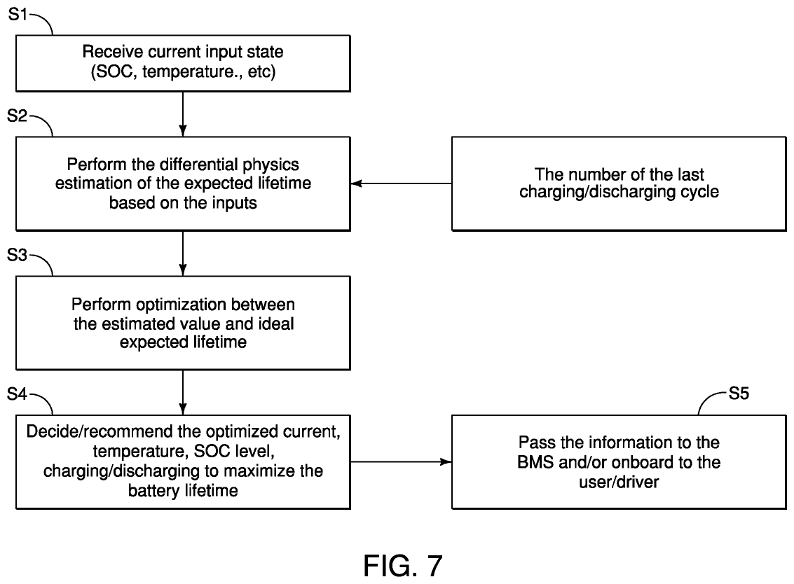

Referring now FIG. 7, a flowchart of the processing steps of the BMS 12 having the differential physics network 22 is illustrated. In step S1, the BMS 12 receives the battery input values at a given time. In step S2, differential physics computation is executed. In step S3, the differential physics network 22 performs optimization. In step S3, the output of the optimization can be used for the next time step such as the optimum temperature, SOC, etc. In step S4, the BMS 12 determines the target output values. In step S5, the BMS 12 can control the battery inputs as necessary, such as increasing the cooling in the battery pack to lower the temperature if needed. It will be apparent to those skilled in the vehicle and the battery field from this disclosure that the time interval of performing the optimization can be pre-programmed or requested on demand for effective operations.

The cost of this differential physics approach is estimated to be in milli-seconds (ms) for optimizing an input target value. This can be written as below for multi-factor optimization:

$$\partial {Q}_{loss} = [ \begin{matrix}{A}_{1} & {B}_{1} & {C}_{1} & {D}_{1} \\ {A}_{2} & {B}_{2} & {C}_{2} & {D}_{2} \\ {A}_{3} & {B}_{3} & {C}_{3} & {D}_{3} \\ {A}_{4} & {B}_{4} & {C}_{4} & {D}_{4}\end{matrix} ] [ \begin{matrix}\partial SOC \\ \partial {P}_{out} \\ \partial {I}_{app} \\ \partial T\end{matrix} ] \qquad Formula 5$$

where ∂Qₗₒₛₛ=y is the capacity loss, Aᵢ, Bᵢ, Cᵢ, and Dᵢ is the pre-coefficient directional relationship between the capacity loss due to the ∂SOC, ∂Pₒᵤₜ, ∂Iₐₚₚ, and ∂T, respectively, change from process i such as SEI growth. More variables can be included in the x matrix of the multi-variables by proper control designing. The target function for optimization or the relationships can always be updated over time with more recent versions (e.g., during maintenance visit or online). This multi-factor optimization of the differential physics network 22 can reduce the computational cost by the BMS 12.

Referring to FIG. 5, a simplified version of the differential physics network 22 is illustrated. Here, the total capacity loss associated with a given battery input value is the sum of loss from each mechanism. For example, the loss in capacity due to the SOC is described as

$$\partial {Q}_{loss} = {\sum }_{1}^{n} {A}_{i} \times \partial SOC \qquad Formula 6$$

where the A is summed over all mechanisms of degradation. In terms of time-dependent optimization, real-time optimization methods can be used to determined next time step optimized input value.

For example, the change in the SOC with respect of time (t) is written as follows

$$\frac{\partial {Q}_{loss}}{\partial t} = {\sum }_{1}^{n} {A}_{i} \times \frac{\partial SOC}{\partial t} \qquad Formula 7$$

such that the optimization is achieved by determining the value of SOC in the next time step for minimizing the loss with respect to time evolution.

The differential physics network 22 can be applied at the cell level, the module level or the battery pack level. When applying it at a given level, the proper layers should be selected only. For example, at the cell level only layers up to the cell level will be considered, as shown in FIGS. 3 and 4. In that case, the capacity loss can be used to balance the current, voltage and temperature between cells for extending the lifetime of each cell. The BMS controller 16 then applies in forward voltage, temperature, or current balance to account for cell-to-cell variations. In this approach, the minimum capacity loss for the cell is used to balance the cell-to-cell variation.

In the illustrated embodiment, a method for determining target control parameters for a vehicle battery is provided. The method comprises detecting a first set of battery state values, detecting a second set of battery state values and utilizing differential physics via a differential physics network 22 to determine the directional relationship of the first and second sets of battery state values to calculate a total battery degradation value. The method further comprises performing optimization via the differential physics network 22 using backpropagation to determine the target control parameters for the vehicle battery. The optimization is performed using a cost function of the total battery degradation based on varying the first and second battery state values.

The method further comprises executing a conversion function via the differential physics network 22 to convert the first and second input values that are detected at a battery module level to a battery cell level. The method further comprises determining via the differential physics network 22 first directional derivative cell level values 40, as illustrated in FIG. 4.

The method further comprises determining via the differential physics network 22 executing differential physics second directional derivative cell level values, as illustrated in FIG. 4. The method further comprises determining via the differential physics network 22 a plurality of capacity loss values (Q₁ . . . Qₙ), each of the capacity loss values being associated with a value from the first and second input values. The method further comprises determining the total battery degradation value Qₗₒₛₛ via the differential physics network 22 executing a summation of the plurality of capacity loss values (Q₁ . . . Qₙ).

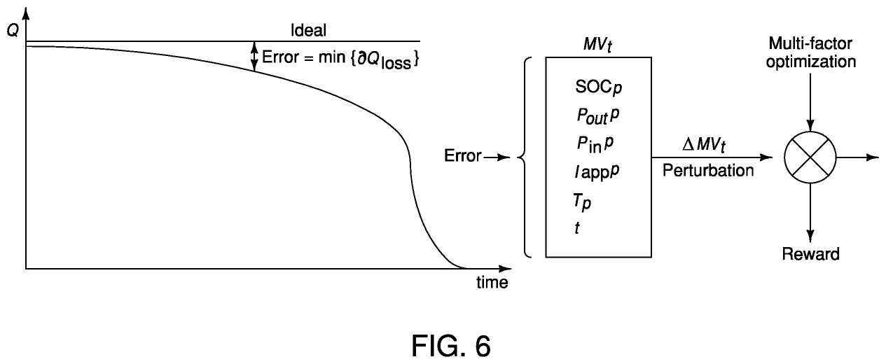

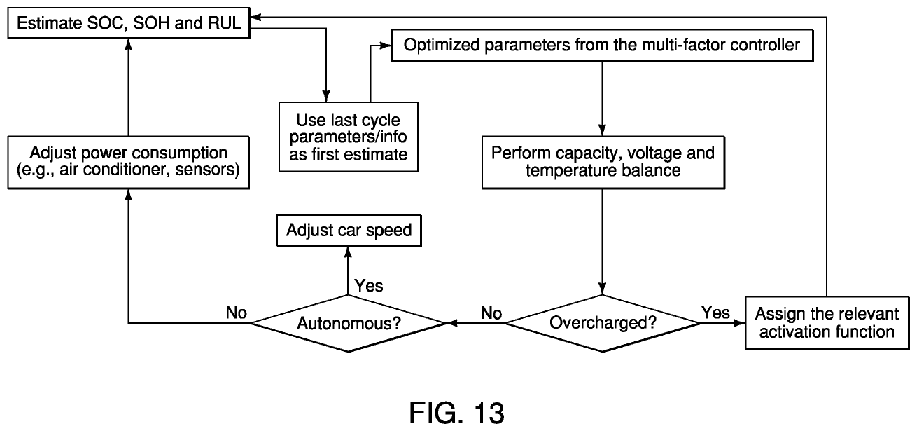

The BMS controller 16 of the BMS 12 will now be further described with reference to FIGS. 6 and 8-13. The BMS controller 16 is a multi-objective multivariable centralized controller that utilizes the differential physics network 22 and implements a reinforcement reward. The BMS controller 16 is preferably connected to vehicle grid, performance, and autonomous driving conditions. For example, the BMS controller 16 can be coupled with the autonomous driving control unit to optimize the car speed and the acceleration events to optimize the battery lifetime. The BMS controller 16 can inform the driver to select a travel route with optimized car speed if the temperature control is not satisfied for maximizing the battery lifetime.

The BMS controller 16 can optimize the charging rate versus battery pack temperature to extend the lifetime of the battery by minimizing the effect of physical mechanisms (e.g., SEI/CEI growth). That is, the BMS controller 16 can perform variable charging/discharging protocol depending on the detected battery states that are the inputs or variables. The BMS controller 16 utilizes several battery states (inputs) as state at the same point. The BMS controller 16 minimizes the error (e.g., extend the lifetime of the battery by reducing battery capacity degradation or loss (Q)).

The BMS controller 16 can expedite the control in the vehicle and link all variables together in one framework. By implementing the BMS controller 16 executing a differential physics network 22 with the vehicle, the number of controllers and sensors in the vehicle can be reduced. The BMS controller 16 can direct the battery management circuitry 14 and other controllers of the vehicle to execute control from cell-level up to the vehicle-level. The BMS controller 16 is preferably integrated with the BMS 12 to account for cell-to-cell variation in terms of capacity, voltage, current and temperature.

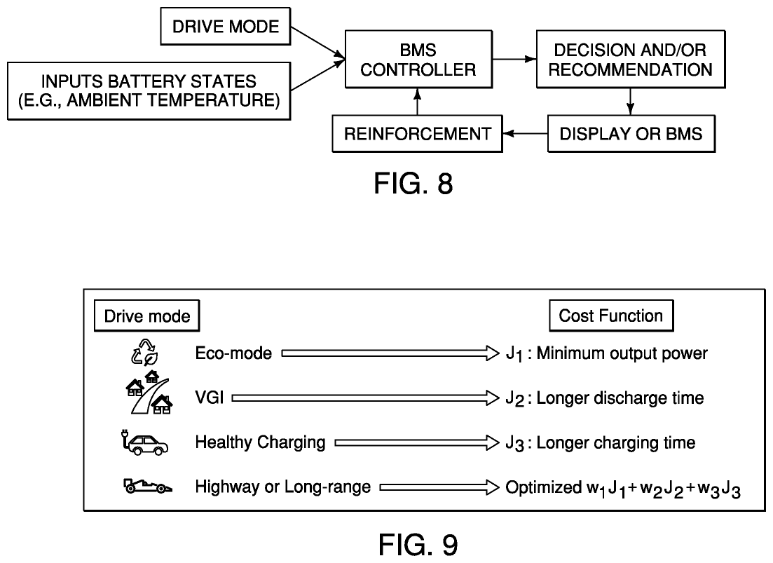

Referring to FIGS. 8 and 9, the BMS controller 16 utilizes pre-coded drive modes of the vehicle which are customized for the user using activation functions. The vehicle drive modes can include an eco-mode, a VGI (vehicle-to-grid integration) mode, healthy charging mode, a highway/long-range mode, amongst others. The eco-mode can be a mode where during driving the output power of the vehicle (AC, speed, sensors, etc.) can be minimized to achieve low discharge rate and therefore healthy battery (less degradation and longer lifetime). For example, the eco-drive mode can be pre-coded to minimize the output vehicle power (cost) with objective to increase the lifetime of the battery

The VGI mode can be used to optimize the discharging rate from the mobile EV to the building/grid to reduce the discharging rate to achieve less degradation (longer lifetime).

The VGI mode can be pre-coded to minimize the discharge time (cost) with objective to increase the lifetime of the battery. The healthy charging mode can reduce the charging rate (C-rate) or find optimum physics-based charging protocol (as a function of time/SOC/SOH) for longer lifetime of batteries. The health-charge mode is pre-coded to minimize the charging time (cost) with objective to increase the lifetime of the battery. The highway/long-range mode can preserve the stored energy in the battery to optimize the discharging, power output and charging (in case of using generative brakes).

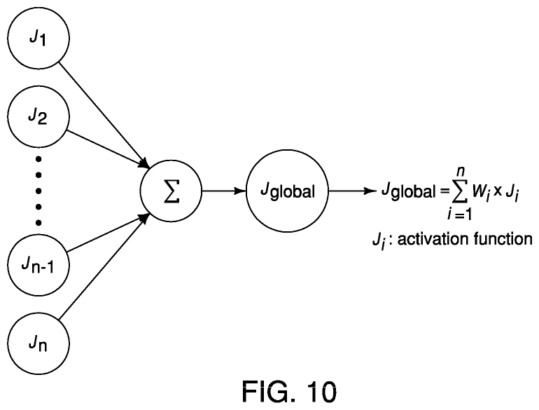

Referring to FIG. 10, the BMS controller 16 is programmed to generate an activation function based on the selected drive mode. The BMS controller 16 optimizes in accordance with the activation function. Each drive mode is activated by the user (using a button in the vehicle or the screen setting in the consoles to operate the mode controller 24). The drive mode can alternatively be preselected by the vehicle. The activation of a drive mode will generate an activation function (wᵢ) that can be used by the BMS controller 16 for optimization as seen FIG. 10. The activation function can have value of either 0 and 1 for each selected drive mode. Alternatively, the activation function can have an optimized value between 0 or 1 for general driving such as highway driving mode.

The cost function can be determined based on the target tunable input. For example, if the optimization is done based on selecting optimized charging protocol, then the optimization cost will be the time of the charging given that slower charging reduces the degradation in the battery. Both the cost function and the activation parameters can be tuned and customized based on the driver behavior. For example, if the driver likes fast charging, then the range of optimization cost function can be automatically updated accordingly through transfer learning processes inside the vehicle. The activation function can also have a function profile such as sigmoid or ramp function to avoid overshooting in the control process and allows damping behavior. Referring to FIG. 10, Jᵢ refers to the cost function of a mode i and wᵢ is the weight of the cost function.

Conventional BMS 12's use de-centralized multiple controllers for each variable resulting in extra computational cost and potentially delayed response or lack of synchronizing between the different variables. With the BMS controller 16 that utilizes the differential physics network 22, optimization of the multi-variables can occur with the singular BMS controller 16 where all of the variables are connected together as shown.

$$\frac{\partial {Q}_{loss}}{\partial t} = [ \begin{matrix}{A}_{1} & {B}_{1} & {C}_{1} & {D}_{1} \\ {A}_{2} & {B}_{2} & {C}_{2} & {D}_{2} \\ {A}_{3} & {B}_{3} & {C}_{3} & {D}_{3} \\ {A}_{4} & {B}_{4} & {C}_{4} & {D}_{4}\end{matrix} ] [ \begin{matrix}\frac{\partial SOC}{\partial t} \\ \frac{\partial {P}_{out}}{\partial t} \\ \frac{\partial {I}_{app}}{\partial t} \\ \frac{\partial T}{\partial t}\end{matrix} ] \qquad Formula 8$$

Alternatively written, the variables can be shown as Formula 9.

$$\frac{\partial {Q}_{loss}}{\partial t} = {\sum }_{1}^{n} {A}_{i} \times \frac{\partial SOC}{\partial t} + {\sum }_{1}^{n} {B}_{i} \times \frac{\partial {P}_{out}}{\partial t} + {\sum }_{1}^{n} {C}_{i} \times \frac{\partial {I}_{app}}{\partial t} + {\sum }_{1}^{n} {D}_{i} \times \frac{\partial T}{\partial t} \qquad Formula 9$$

The BMS controller 16 allows for optimization as a function of time and can be represented below.

$$\partial t = {t}_{next} - {t}_{current} . \qquad Formula 10$$

In this way, the battery values for the next use can be optimized. Since the optimization is achieved based on multi-variables (multiple inputs or detected battery state values), perturbation analysis can be used in real-time to assess the best variable to change in terms of quickest response, maintaining the physical constraints, and maximizing the driver experience. That is, the BMS controller 16 performs sensitivity analysis to find the best variables to change (it can be single variables or several variables with different adjustment within physical constraints which are pre-programmed such as ensuring the temperature does not go up or down by large amount). To speed up the perturbation processes, the BMS controller 16 utilizes a reinforcement agent to give reward for the best variable to change in the next time step.

Then, the optimized parameters are used to backpropagate the capacity, voltage and temperature balance for achieving optimum cell-to-cell balancing while extending the lifetime of the battery. Upon performing backpropagation, the BMS controller 16 is further programmed to control the battery management circuitry 14 in accordance with a target vehicle ambient temperature value, a target vehicle state of charge value, a target vehicle output power value, a target applied current value, and a target battery pack temperature value, as seen in FIG. 12. Upon backpropagation, the BMS controller 16 is further programmed to control the battery management circuitry 14 in accordance with a target vehicle charging/discharging rate value, a target vehicle speed value, a target vehicle power input value, a target minimum battery voltage value, a target maximum battery voltage value, a target minimum battery temperature value, a target maximum battery temperature value, and a target depth of discharge value, as seen in FIG. 12.

For example, if the BMS controller 16 determines that the battery cells are overcharged and connected to the VGI, then the BMS controller 16 can control the charging/discharge protocol via the BMS 12 such that discharge takes place in accordance with a target discharge rate value. If the vehicle is not connected to VGI and under autonomous driving, then the BMS controller 16 can send target vehicle speed values so that the vehicle speed can be adjusted to be within an accepted range to minimize the power output. If the vehicle is not undergoing autonomous driving, then the BMS controller 16 can control the output power by controlling any of the controllers for the air conditioner, sensors or any other car components in accordance with a target vehicle input value. The SOC, SOH, and RUL are estimated and stored in a memory of the BMS controller 16 for the next step of optimization.

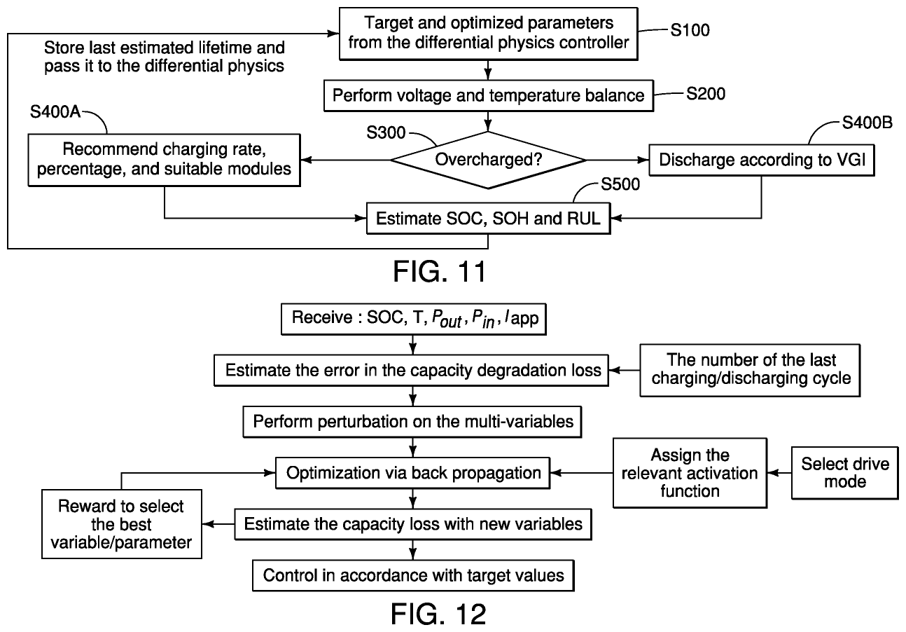

Referring to FIG. 11, a flowchart of the processing steps of the BMS controller 16 of the BMS 12 having the differential physics network 22 integrated therein is illustrated. In step S100, the BMS controller 16 of the BMS 12 receives the target input values. In step S200, the BMS controller 16 utilizes the target input values on the cell level and transmits the target input values to the battery management circuitry 14 for preforming temperature, voltage or any other balancing. In step S300, the BMS controller 16 determines if there is overcharge. In steps S400A and S400B, the BMS controller 16 can recommend protocols to the battery management circuitry 14 accordingly. For example, if the SOC is high and the cell is overcharged, then the BMS 12 will discharge some of the cell SOC via VGI (vehicle-grid integration) if it is connected to the grid. If not connected to the grid, then charging rate, SOC level or discharging from suitable modules will be carried out. In step S500, then the BMS 12 will estimate SOC, SOH, or RUL and store that for the next optimization step in the BMS controller 16.

The BMS controller 16 uses a reinforcement agent to determine which the most effective parameter to change via sensitivity/perturbation analysis (e.g., quicker response, less adverse effect on the battery, and achieve the highest EV performance). Further, the BMS controller 16 can be coupled with the autonomous driving control unit to optimize the car speed and the acceleration events to optimize the battery lifetime. For example, the BMS controller 16 can inform the driver unit to select a travel route with optimized car speed if the temperature control is not satisfied for maximizing the battery lifetime.

The BMS controller 16 generates output such as target battery state values or control values for changing the inputs to reduce capacity loss. The target battery state values or control values can be sent to the BMS 12 for direct real-time update or shared with the driver for manual updating. The proposed controller focuses on optimizing the temperature in the battery pack, temperature in the interior, stacking pressure between the battery cells and charging/discharging rate to minimize the battery pack degradation.

The BMS controller 16 can reduce the complexity in the control system of the BMS 12 by using centralized multi-variable optimization. The BMS controller 16 is considered user-friendly which brings performance satisfaction. The BMS controller 16 approach can extend the lifetime of the battery up to thirty percent, achieves optimized performance, offers longer range, and enables physics-based VGI. Optimizing the inputs to control the growth of the SEI/CEI can allow for extending the battery lifetime by ten percent. This approach will reduce the number of controllers in the BMS 12 (the number of removed controller is proportional to number of the multi-factor variables in the controller).

The BMS controller 16 that utilizes the differential physics network 22 allows for a computationally cost-effective method for decreasing battery capacity loss because the overall system does not try to compute or estimate the actual value of each factor of the battery degradation or the overall degradation in the battery pack. Instead, the system uses directional information (i.e., partial derivatives) based on the real-time conditions to optimize the input values towards extending the lifetime of the battery pack. As described, optimization is carried out via backpropagation to minimize the error/difference/loss between the ideal capacity and the current capacity.

The BMS controller 16 realizes technological improvements of connecting multiple variables (inputs or battery state values) at different scales for controlling the battery degradation conditions. For example, the environment temperature (e.g, T_{amb}) at macroscopic level can be connected to the degradation of the SEI and CEI layers at nanoscale via directional derivatives which links the macroscopic input with the nanoscale effect through going across the vehicle level, the battery pack level, the module level and the cell-level. The BMS controller 16 allows for a quick, cheap and accurate approach as the centralized controller allows for a reduction of computational cost as compared with conventional controllers.

The differential physics network 22 can be modified to account for different inputs or physics relationships. The differential physics network 22 and the BMS controller 16 described herein are not limited to any specific battery type or chemistry. The differential physics network 22 can be utilized to maximize the lifetime of the battery using directional relationships without the need to perform expensive calculations on-board the vehicle. The target function for optimization or the relationships can always be updated over time with more recent versions (e.g., during maintenance visit or online).

The BMS controller 16 includes a processor or CPU that controls the operation of the vehicle control apparatus. As used herein, the terminology “processor” indicates one or more processors, such as one or more special purpose processors, one or more digital signal processors, one or more microprocessors, one or more controllers, one or more microcontrollers, one or more application processors, one or more Application Specific Integrated Circuits, one or more Application Specific Standard Products; one or more Field Programmable Gate Arrays, any other type or combination of integrated circuits, one or more state machines, or any combination thereof.

The BMS controller 16 further has a computer readable medium or memory storing the sound output options. As used herein, the terminology “memory” or “computer-readable medium” (also referred to as a processor-readable medium) indicates any computer-usable or computer-readable medium or device that can tangibly contain, store, communicate, or transport any signal or information that may be used by or in connection with any processor. For example, the computer-readable medium may be one or more read only memories (ROM), one or more random access memories (RAM), one or more registers, low power double data rate (LPDDR) memories, one or more cache memories, one or more semiconductor computer readable medium devices, one or more magnetic media, one or more optical media, one or more magneto-optical media, or any combination thereof.

Therefore, the computer-readable medium further includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media can include, for example, optical or magnetic disks and other persistent computer readable medium. Volatile media may include, for example, dynamic random access computer readable medium (DRAM), which typically constitutes a main computer readable medium.

The memory can also be provided in the form of one or more solid state drives, one or more computer readable medium cards, one or more removable media, one or more read-only memories, one or more random access memories, one or more disks, including a hard disk, a floppy disk, an optical disk, a magnetic or optical card, or any type of non-transitory media suitable for storing electronic information, or any combination thereof.

The processor of the BMS controller 16 can execute instructions transmitted by one or more transmission media, including coaxial cables, copper wire and fiber optics, including the wires that comprise a system bus coupled to a processor of a computer. As used herein, the terminology “instructions” may include directions or expressions for performing any method, or any portion or portions thereof, disclosed herein, and may be realized in hardware, software, or any combination thereof.

For example, instructions may be implemented as information, such as a computer program, stored in computer readable medium that may be executed by a processor to perform any of the respective methods, algorithms, aspects, or combinations thereof, as described herein. In some embodiments, instructions, or a portion thereof, may be implemented as a special purpose processor, or circuitry, that may include specialized hardware for carrying out any of the methods, algorithms, aspects, or combinations thereof, as described herein. In some implementations, portions of the instructions may be distributed across multiple processors on a single device, on multiple devices, which may communicate directly or across a network such as a local area network, a wide area network, the Internet, or a combination thereof.

Computer-executable instructions can be compiled or interpreted from computer programs created using a variety of programming languages and/or technologies, including, without limitation, and either alone or in combination, Java™, C, C++, Visual Basic, Java Script, Perl, etc. In general, the processor receives instructions from the computer-readable medium and executes these instructions, thereby performing one or more processes, including one or more of the processes described herein. Such instructions and other data may be stored and transmitted using a variety of computer-readable media.

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts.

The term “detect” as used herein to describe an operation or function carried out by a component, a section, a device or the like includes a component, a section, a device or the like that does not require physical detection, but rather includes determining, measuring, modeling, predicting or computing or the like to carry out the operation or function.

The term “configured” as used herein to describe a component, section or part of a device includes hardware and/or software that is constructed and/or programmed to carry out the desired function.

The terms of degree such as “substantially”, “about” and “approximately” as used herein mean a reasonable amount of deviation of the modified term such that the end result is not significantly changed.

The following glossary of terms can be referenced with reference to the Figures.

### Glossary of Terms

| Variable | Description |
|---|---|
| T_{amb} | Ambient temperature |
| SOC | State-of-charge of the EV |
| Pₒᵤₜ | Output power from the EV |
| Iₐₚₚ | Applied current during charging or regenerative braking |
| T | The estimated temperature at the battery pack level |
| Cᵣₐₜₑ | The charging/discharging rate of the EV |
| u | The speed of the EV |
| Pᵢ | The power input to the EV (e.g., regenerative brakes) |
| Vₘᵢₙ | Minimum voltage in the battery pack |
| Vₘₐₓ | Maximum voltage in the battery pack |
| Tₘᵢₙ | Minimum temperature in the battery pack |
| Tₘₐₓ | Maximum temperature in the battery pack |
| DOD | Depth of discharge |
| M_{pack/cell} | Conversion function of the macroscopic parameters at the |
| | pack/module level to the cell level. This function is determine |
| | based on the battery pack architecture (i.e., equivalent circuit |
| | of the parallel and series connections of the cells) |
| V_{ocv} | Open-circuit voltage of the cell |
| I_{cell} | Electrical current at the cell level |
| V_{cell} | Electrical voltage at the cell level |
| T_{cell} | Temperature at the cell level |
| Lₛₑᵢ | Thickness of the SEI |
| L_{cei} | Thickness of the CEI |
| N_{age} | Current actual cycle number considering the DOD and aging |
| | over time |
| R_{Li} | Electrical resistance of Lithium-ion cell |
| Qᵢ | Capacity loss due to factor i |
| | Summation |
| Qₗₒₛₛ | Total capacity loss/degradation |
| aᵢ^{j} | The directional derivative between two variables where j is the |
| | variable level (1 for EV level, 2 for pack level, 3 for cell |
| | level, and 4 for mechanism level), i is the degradation factor |
| J | The cost function of the degradation |
| Aᵢ | The total directional coefficient (i.e., multiplication of |
| | aᵢ^{j} across the levels 1-4) for degradation factor i due to SOC |
| | change. |
| Bᵢ | The total directional coefficient (i.e., multiplication of |
| | aᵢ^{j} across the levels 1-4) for degradation factor i due to power |
| | output change. |
| Cᵢ | The total directional coefficient (i.e., multiplication of |
| | aᵢ^{j} across the levels 1-4) for degradation factor i due to applied |
| | current change. |
| Dᵢ | The total directional coefficient (i.e., multiplication of |
| | aᵢ^{j} across the levels 1-4) for degradation factor i due to |
| | temeprature change. |
| C | Concentration |
| t | time |
| wᵢ | Activation function of drive mode i |
| ΔMVₜ | Targeted multi-variables |

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts.

The term “detect” as used herein to describe an operation or function carried out by a component, a section, a device or the like includes a component, a section, a device or the like that does not require physical detection, but rather includes determining, measuring, modeling, predicting or computing or the like to carry out the operation or function.

The term “configured” as used herein to describe a component, section or part of a device includes hardware and/or software that is constructed and/or programmed to carry out the desired function.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. A non-transitory differential physics network disposed upon a non-transitory computer readable storage medium and executable by a computer, the non-transitory differential physics network comprising:
an input layer to which first input values related to a first set of detected battery state values is input;
an output layer from which a total capacity loss value is output; and
an intermediate layer to which second input values related to a second set of detected battery state values is input, each of the first set of detected battery state values is connected by a directional relationship to each of the second set of detected battery state values,
the differential physics network utilizing differential physics to determine the directional relationship of the first and second sets of detected battery state values to output the output layer, the differential physics network performing optimization using backpropagation to determine target input values for the input layer.

2. The non-transitory differential physics network according to claim 1, further comprising
a conversion layer executing a conversion function that converts the first and second input values that are detected at a battery module level to a battery cell level.

3. The non-transitory differential physics network according to claim 2, wherein
the differential physics network performs optimization during real-time battery use.

4. The non-transitory differential physics network according to claim 3, wherein
the optimization is performed using a cost function of the total capacity loss value based on varying the first and second input values.

5. The non-transitory differential physics network according to claim 4, wherein
the first set of detected battery state values includes any one or more of a vehicle ambient temperature value, a vehicle state of charge value, a vehicle output power value, an applied current value, and a battery pack temperature value.

6. The non-transitory differential physics network according to claim 5, wherein
the second set of detected battery state values includes any one or more of a vehicle charging/discharging rate value, a vehicle speed value, a vehicle power input value, a minimum battery voltage value, a maximum battery voltage value, a minimum battery temperature value, a maximum battery temperature value, and a depth of discharge value.

7. The non-transitory differential physics network according to claim 6, wherein
the conversion layer outputs first directional derivative cell level values including any one or more of an open-circuit voltage value, an electrical current value, an electrical voltage value, and a temperature value.

8. The non-transitory differential physics network according to claim 7, wherein
the conversion layer outputs second directional derivative cell level values including any one or more of an solid electrolyte interface thickness value, a cathode electrolyte interphase thickness value, a current cycle number value, a electrical resistance value.

9. The non-transitory differential physics network according to claim 8, wherein
the output layer generates the total capacity loss value based on a plurality of capacity loss values, each of the capacity loss values being associated with a value from the first and second input values.

10. The non-transitory differential physics network according to claim 9, wherein
the total capacity loss value of the output layer is determined from a summation of the plurality of capacity loss values.

11. A method for determining target control parameters for a vehicle battery, the method comprising:
detecting a first set of battery state values;
detecting a second set of battery state values;
utilizing differential physics via a differential physics network to determine the directional relationship of the first and second sets of battery state values to calculate a total capacity loss value; and
performing optimization via the differential physics network using backpropagation to determine the target control parameters for the vehicle battery.

12. The method according to claim 11, further comprising
executing a conversion function via the differential physics network to convert the first and second input values that are detected at a battery module level to a battery cell level.

13. The method according to claim 12, wherein
the optimization is performed using a cost function of the total capacity loss value based on varying the first and second battery state values.

14. The method according to claim 13, wherein
the first set of battery state values includes any one or more of a vehicle ambient temperature value, a vehicle state of charge value, a vehicle output power value, an applied current value, and a battery pack temperature value.

15. The method according to claim 14, wherein
the second set of battery state values includes any one or more of a vehicle charging/discharging rate value, a vehicle speed value, a vehicle power input value, a minimum battery voltage value, a maximum battery voltage value, a minimum battery temperature value, a maximum battery temperature value, and a depth of discharge value.

16. The method according to claim 15, further
determining via the differential physics network executing differential physics first directional derivative cell level values including any one or more of an open-circuit voltage value, an electrical current value, an electrical voltage value, and a temperature value.

17. The method according to claim 16, wherein
determining via the differential physics network executing differential physics second directional derivative cell level values including any one or more of an solid electrolyte interphase thickness value, a cathode electrolyte interphase thickness value, a current cycle number value, an electrical resistance value.

18. The method according to claim 17, further comprising
determining via the differential physics network a plurality of capacity loss values, each of the capacity loss values being associated with a value from the first and second input values.

19. The method according to claim 18, wherein
determining the total capacity loss value via the differential physics network executing a summation of the plurality of capacity loss values.
